(19) United States
(12) Patent Application Publication
(10) Pub. No.: US 2023/0260873 A1
(43) Pub. Date: Aug. 17, 2023

(54) THREE-DIMENSIONAL FLOW BALANCE FOR POWER MODULE COOLING

(71) Applicants: George R. Woody, Clinton, AR (US); David L. Bogdanchik, Pasadena, CA (US)

(72) Inventors: George R. Woody, Clinton, AR (US); David L. Bogdanchik, Pasadena, CA (US)

(21) Appl. No.: 17/672,681

(22) Filed: Feb. 15, 2022

(51) Int. Cl. H01L 23/473; H05K 7/20

(52) U.S. Cl. CPC H01L 23/473; H05K 7/20436; H05K 7/20945

(57) ABSTRACT

A low profile semiconductor heat dissipation apparatus utilizing innovative three dimensional flow balancing to achieve both greater thermal efficiency and greater heat dissipation uniformity.

### CROSS-REFERENCE TO RELATED APPLICATIONS

This United States Non-Provisional Utility patent application claims the priority date of U.S. Provisional Application No. 63/149,585, titled: “THREE DIMENSIONAL FLOW BALANCE FOR POWER MODULE COOLING,” filed Feb. 15, 2021 in the United States Patent and Trademark Office, the disclosure of which is hereby incorporated by reference in its entirety.

### FIELD OF THE PRESENT DISCLOSURE

This disclosure relates generally to semiconductor heat dissipation technology and more specifically to an improved semiconductor heat dissipation apparatus utilizing an innovative three-dimensional flow balancing design to yield more uniform and thermally efficient heat transfer.

### BACKGROUND OF THE RELATED ART

When designing power electronics, such as inverters, converters, chargers, etc. . . . , heat dissipation is a critical issue. Excessive heat can lead to premature deterioration of both physical and electrical properties which, in turn, can cause both intermittent and permanent failures. Further, even when operating within acceptable temperature ranges, the ability to operate at cooler temperatures is almost always desirable because cooler operating temperatures typically provide increased electrical efficiency, greater long-term reliability, greater high performance capability, and/or the ability to shrink the power electronic components into a smaller and/or more low-profile design footprint. In almost all highly competitive fields of electronic technology, the above aforementioned advantages are of critical importance so even marginal increases in heat dissipation efficiency can be of great importance.

To achieve greater heat dissipation capability, power semiconductor devices are often coupled with a heat sink of some variety which is in direct contact or thermal communication with a cooling fluid that is capable of drawing heat energy from a heat transfer surface and transporting the heat energy elsewhere for ultimate dissipation.

One such device is described in U.S. Pat. No. 10,892,208 (“the '208 patent”). The '208 patent describes a heat dissipation device capable of achieving higher heat transfer efficiency than its contemporary designs by utilizing flow balancers to manipulate the hydrodynamic pressure of cooling fluid in two dimensions so as to intentionally regulate the flow of cooling fluid across the heat exchanging surface.

When the '208 legacy design is in a vertical orientation, cooling fluid enters the apparatus through an influent that leads to a first, upper plenum and then travels past a heat exchange surface until it reaches a second, lower plenum and finally exits the apparatus through an effluent. The significant innovation of the heat dissipation device disclosed in the '208 patent is the existence of “flow balancers” located in either the first, upper plenum, or the second, lower plenum, or both, which are designed to alter the internal cross-sectional area of the plenum(s) within which the flow balancers are located, which, in turn, alters the hydrostatic pressure and regulates the flow distribution of the cooling fluid across the heat transfer surface.

As disclosed in the '208 patent, such increased regulation of the flow distribution theoretically reduces a power semiconductor's junction temperature by as much as twenty-five percent (25%), according to Computational Fluid Dynamics (CFD), and has been demonstrated to reduce the junction temperatures up to thirty-three percent (33%) during actual testing.

While such two-dimensional flow balance control has demonstrated impressive results in both theory and in practice, there is still room for further improvement because the rate of heat transfer is not uniform in the direction of the coolant flow because as the cooling fluid flows across the heat transfer surface it absorbs heat and the temperature delta between the heat transfer surface and the cooling fluid narrows thus reducing the rate of heat transfer creating non-uniform heat transfer across the heat transfer surface.

This natural degradation of thermal efficiency could be mitigated if the heat transfer coefficient of the cooling fluid could increase dynamically as the temperature delta decreased which would occur if the flow rate increased such that the cooling fluid transitioned from laminar to turbulent flow. Such transition is possible to induce if the cooling fluid is regulated from the third dimension as it flows across the heat transfer surface. There exists a need for a heat dissipation apparatus capable of three dimensional regulating of the cooling fluid.

The present disclosure distinguishes over the related art providing heretofore unknown advantages as described in the following summary.

### BRIEF SUMMARY OF THE INVENTION

The present disclosure describes a novel and innovative heat dissipation apparatus that is more thermally efficient than legacy designs, comprising at least one power semiconductor device in direct contact or in thermal communication with a heat sink, and a manifold capable of three-dimensionally regulating the flow of coolant fluid across the heat sink. The primary innovative advantage of the three-dimensional flow regulation is that it yields more uniform and efficient heat transfer across the heat transfer surface.

The apparatus is intended for cooling a variety of semi-conductor dies such as, but not limited to IGBTs, SI MOSFETs, SiC MOSFETs, JFETs, DIODES for use in power electronics such as inverters, converters, chargers, etc. The semi-conductor die should be in direct contact or close thermal communication with the heat sink.

The opposing side of the heat sink may feature fins such as micro fins or pin fins. Such pins may be round, square, or some other shape designed to maximize surface area for contact with cooling fluid and encourage heat transfer.

Coupled to the heat sink is a manifold designed to accept and guide the flow of a cooling fluid across the heat sink to accept the heat energy and carry it away for dissipation elsewhere. The manifold comprises an influent to accept the cooling fluid, a first and second manifold, a plurality of channels connecting the first and second manifold, and an effluent to allow the cooling fluid to exit.

Similar to legacy designs, the first and second plenum feature internal flow balancing features, if necessary, to achieve equal hydrostatic pressure between each connecting channel to ensure equivalent division of coolant fluid through each channel. This is achieved by narrowing the plenum wall in strategic locations to increase hydrodynamic pressure where necessary. This is referred to a two-dimensional flow balancing.

The novelty of the presently disclosed apparatus is the additional thermal efficiency and heat transfer uniformity achieve throw the third dimension of flow balancing. The third dimension of flow balancing is achieved by introducing a gradient in the x-axis direction (as opposed to narrowing in the y-z plane in which the previous flow balancing was achieved) to narrows the channels progressively from influent to effluent.

The effect of the narrowing of the channels progressively from influent to effluent is to cause the cooling fluid flow rate to increase. If the initial flow rate and channel size is properly calibrated, the gradient can cause the cooling fluid to transition from laminar flow to turbulent flow during its passage through the channel. A beneficial byproduct of forcing this transition is that the cooling fluid's heart transfer coefficient will increase, thereby making the coolant fluid more efficient as it passed through the channel. This increase in heat transfer coefficient will compensate for the cooling fluid's natural decrease in thermal efficiency as the temperate of the cooling fluid rises due to the absorbed heat energy.

Thus properly balances, the presently disclosed heat transfer apparatus will gradually increase the heat transfer coefficient as the channel narrows to the point where thlaminar in flow at the entrance and becomes more turbulent at the exit

This claim will compensate for lower inlet coolant temperature which will increase as the coolant absorbs heat dissipated from the module semi-conductors. The coolant temperature at the exit of coolant will be higher than the coolant temperature at the entrance

With proper balance of this principle by applying the reduced heat transfer coefficient at the entrance with cooler coolant, the junction of the semi-conductor die at the entrance can be maintained to equal the junction temperature at the exit point of the manifold by increased heat transfer via smaller cross section flow area. The junction temperature at the exit point is normally higher due to the increase in coolant temperature at that point

The advantage is higher reliability and better current sharing of semi-conductors with more uniform temperatures of the die.

This disclosure teaches certain benefits in construction and use which give rise to the objectives described below.

A primary objective inherent in the above-described apparatus is to provide advantages not taught by the prior art.

Another objective is to provide a power semiconductor heat dissipation apparatus with flow balancing in three dimensions for increased heat dissipation efficiency.

A further objective is to provide a power semiconductor heat dissipation apparatus with more uniform increased heat dissipation efficiency across the heat dissipation surface.

A still further objective is to provide a low profile power semiconductor heat dissipation apparatus with greater heat dissipation efficiency.

Other features and advantages of the present invention will become apparent from the following more detailed description, taken in conjunction with the accompanying drawings, which illustrate, by way of example, the principles and features of the presently described apparatus.

### BRIEF DESCRIPTION OF THE SEVERAL VIEWS OF THE DRAWING(S)

The accompanying drawings illustrate various exemplary implementations and are part of the specification. The illustrated implementations are proffered for purposes of example not for purposes of limitation. Illustrated elements will be designated by numbers. Once designated, an element will be identified by the identical number throughout. Illustrated in the accompanying drawing(s) is at least one of the best mode embodiments of the present disclosure. In such drawing(s):

FIG. 1 is a perspective view of the presently disclosed heat dissipation apparatus capable of three dimensional flow balancing for increased heat dissipation uniformity.

FIG. 2 is a cutaway perspective view of the presently disclosed heat dissipation apparatus illustrating the orientation of the power semiconductor device to the heat sink and the flow balanced manifold.

FIG. 3 is a perspective view of the manifold of the presently disclosed heat dissipation apparatus illustrating the various features that enable the apparatus to balance coolant fluid flow in three dimensions.

FIG. 4 is a cross-sectional plan view of the presently disclosed heat dissipation apparatus illustrating the features designed to balance coolant fluid flow in the third dimension.

FIG. 5 is a perspective view of a different embodiment of the manifold of the presently disclosed heat dissipation apparatus than the manifold embodiment shown in FIG. 3 to illustrate an alternative possible design.

### DETAILED DESCRIPTION OF THE EXEMPLARY EMBODIMENT

The above-described drawing figures illustrate an exemplary embodiment of presently disclosed apparatus and its many features in at least one of its preferred, best mode embodiments, which is further defined in detail in the following description. Those having ordinary skill in the art may be able to make alterations and modifications to what is described herein without departing from its spirit and scope of the disclosure. Therefore, it must be understood that what is illustrated is set forth only for the purposes of example and that it should not be taken as a limitation in the scope of the present apparatus or its many features.

Described now in detail are a series of drawings depicting various features and details for the purpose of further clarifying the presently disclosed apparatus and method.

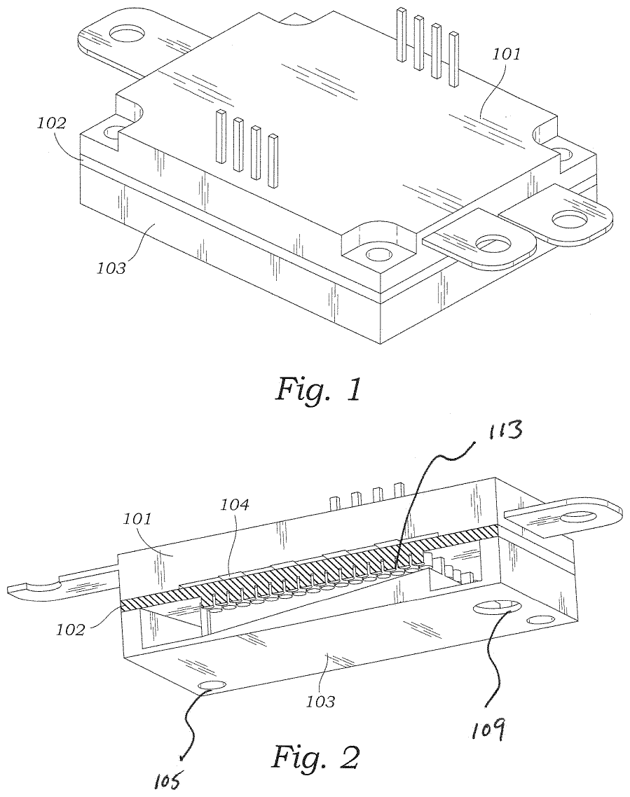

FIG. 1 is a perspective view of an exemplar embodiment of the presently disclosed innovative heat dissipation apparatus 100 illustrated including an exemplar encapsulated semiconductor device 101, shown with eight power and/or signal leads extending out from the apparatus 100. The semiconductor device 101 is also shown affixed to a heat sink 102, which is coupled with a manifold 103 capable of three-dimensionally regulating coolant fluid flow across the heat sink 102 for more uniform, thermally efficient heat transfer.

FIG. 2 is a perspective cutaway view of the presently disclosed apparatus 100 illustrating some internal features to the presently disclosed apparatus 100 such as the exemplar round pin fin features 113 of the heat sink 102. As previously stated, the heat sink 102 can feature fins of a variety of shapes and sizes so long as they increase surface area and encourage greater heat transfer. From the perspective view of FIG. 2, two apertures in the manifold 103 are visible; one aperture serves as an influent 105 for cooling fluid entry, and the other serves as an effluent 109 for cooling fluid exit.

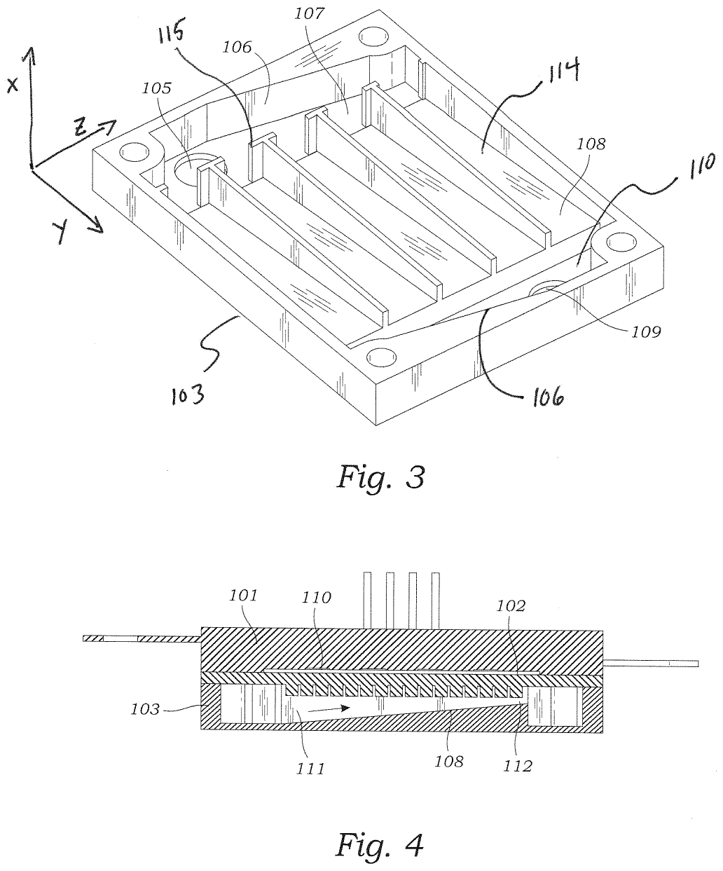

FIG. 3 illustrates a perspective view of the manifold 103 shown separately from the other major components to illustrate the internal features that serve to regulate the flow of coolant fluid. The coolant fluid first enters the manifold 103 through the influent aperture 105 which leads immediately to the first plenum 107. The hydrostatic pressure of the coolant fluid flowing through the first plenum 107 is balances in the z-axis direction by the flow-balancing wall gradient feature 106 which narrows the first plenum 107 in the Z-axis direction.

The pressure balanced coolant fluid then enters a plurality of channels 114 that connect the first plenum 107 to the second plenum 110. The number of channels 114 is not critical to the presently disclosed apparatus but there but there should be a more than one such that flow is generally restricted to flow in the direction of the y-axis after the coolant fluid enters the channel 114. The flow balancing feature 106 should ensure that coolant fluid entering each channel 114 is experiencing roughly equal hydrodynamic pressure; however, balancing can be fine-tuned with gate restriction features 115 at the entrance of each channel 114.

When the coolant fluid has reached the end of the channel 114 it will enter the second plenum 110 and exit the apparatus through the effluent 109. The hydrostatic pressure of the coolant fluid in the second plenum 110 is balanced with a wall gradient feature 106 similar to the one illustrated in the first plenum 107. The manifold illustrated in FIG. 3 is an exemplar embodiment, other embodiment may not include a wall gradient feature 106 in both the first plenum 107 and the second plenum 110. Other embodiments may include a wall gradient feature in only the first plenum 107 or the second plenum 110, or possibly neither the first nor the second plenum 107, 110.

FIG. 4 illustrates a cross-sectional plan view of the presently disclose device showing an gradient in the x-axis direction 108 along the channel 114. This gradient feature 108 of the channel 114 is responsible for the flow balancing in the third dimension. By narrowing the channel 114 in the x-axis direction as the cooling fluid flows in the y-axis direction, the channel 114 increases the flow velocity of the coolant fluid as it passes along the heat transfer surface causing the fluid to transition from laminar flow to turbulent flow which, in turn, changing the coolant fluids heat transfer coefficient.

If the flow rate of the coolant fluid and the gradient of the channel 114 are appropriately balanced, the coefficient of heat transfer of the coolant fluid will begin to increase due to its transition toward turbulent flow, thereby compensating for the otherwise reduction of thermal efficiency experienced due to the raise in temperature of the coolant fluid do to the absorbed heat energy. This “third-dimension” flow balancing has been shown to achieve increased thermal efficiency both theoretically through Computational Fluid Dynamics (CFD) and during actual testing. It is important to note that to achieve such results the flow rate and channel restriction must be properly calibrated to the material properties of the coolant fluid such that the coolant fluid experiences transition while flowing through the channel 114.

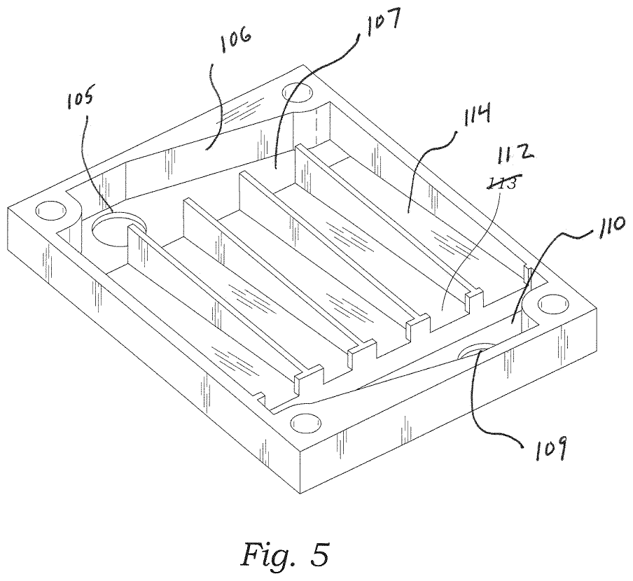

FIG. 5 illustrates another embodiment of the manifold wherein gate features 115 at the exit of the channel 114 are used instead of at the beginning of the channel as illustrated in FIG. 4. Alternative embodiments are possible so long as the flow balancing features cause the cooling fluid to experience transition from laminar to turbulent flow during its journey across the heat transfer surface.

The enablements described in detail above are considered novel over the prior art of record and are considered critical to the operation of at least one aspect of the apparatus and its method of use, and to the achievement of the above-described objectives. The words used in this specification to describe the instant embodiments are to be understood not only in the sense of their commonly defined meanings, but to include by special definition in this specification: structure, material, or acts beyond the scope of the commonly defined meanings. Thus, if an element can be understood in the context of this specification as including more than one meaning, then its use must be understood as being generic to all possible meanings supported by the specification and by the word(s) describing the element.

The definitions of the words or drawing elements described herein are meant to include not only the combination of elements which are literally set forth, but all equivalent structures, materials or acts for performing substantially the same function in substantially the same way to obtain substantially the same result. In this sense it is therefore contemplated that an equivalent substitution of two or more elements may be made for any one of the elements described and its various embodiments or that a single element may be substituted for two or more elements in a claim.

Changes from the claimed subject matter as viewed by a person with ordinary skill in the art, now known or later devised, are expressly contemplated as being equivalents within the scope intended and its various embodiments. Therefore, substitutions, now or later known to one with ordinary skill in the art, are defined to be within the scope of the defined elements. This disclosure is thus meant to be understood to include what is specifically illustrated and described above, what is conceptually equivalent, what can be obviously substituted, and also what incorporates the essential ideas.

The scope of this description is to be interpreted only in conjunction with the appended claims and it is made clear, here, that each named inventor believes that the claimed subject matter is what is intended to be patented.

What is claimed:

1. An apparatus for of dissipating heat from power semiconductor devices, the apparatus comprising:
A device as disclosed in accompanying specification
